(19) United States
(12) Patent Application Publication
(10) Pub. No.: US 2026/0122839 A1
(43) Pub. Date: Apr. 30, 2026

(54) LIQUID-COOLING HEAT DISSIPATION DEVICE

(71) Applicant: ALPHA NETWORKS INC., Hsinchu (TW)

(72) Inventors: CHIH-KUANG WANG, Hsinchu (TW); YU-CHU TANG, Hsinchu (TW); MING-YI WEN, Hsinchu (TW); GUAN-FU LIN, Hsinchu (TW)

(73) Assignee: ALPHA NETWORKS INC., Hsinchu (TW)

(21) Appl. No.: 19/081,880

(22) Filed: Mar. 17, 2025

(30) Foreign Application Priority Data
Oct. 29, 2024 (TW) 113141228

(51) Int. Cl. H05K 7/20

(52) U.S. Cl. CPC H05K 7/20254; H05K 7/20272

(57) ABSTRACT

A liquid-cooling heat dissipation device includes a case, a floating heat spreader, and a retaining structure. A chamber is formed in the case. A main channel is formed in the chamber. A surface of the case is provided with a shallow groove formed by recessing and a retaining structure combining portion. A combining opening is formed in the shallow groove and communicates with the main channel. The floating heat spreader includes a base plate located in the shallow groove, an abutting plate connected to the base plate, and a plurality of fins connected to the base plate. The base plate and an inner wall of the shallow groove jointly clamp a seal ring. The fins pass through the combining opening and extend into the main channel. The retaining structure is combined with the retaining structure combining portion and engages with a peripheral edge of the base plate.

### BACKGROUND OF THE INVENTION

### Technical Field

The present invention relates generally to a cooling device, and more particularly to a liquid-cooling heat dissipation device.

### Description of Related Art

A plurality of sockets for a plurality of small form-factor pluggable transceivers are disposed on a printed circuit board of a conventional network communication device. In the below description, each of the small form-factor pluggable transceivers is abbreviated as SFP. The conventional SFPs are cooled down by air cooling. An independent air-cooling heat dissipation device is disposed on each of the sockets of the SFPs. A part of each of the air-cooling heat dissipation devices extends into each of the sockets. Through a downward force applied by an elastic piece, each of the air-cooling heat dissipation devices could be pushed up by each of the SFPs and then could be well in contact with each of the SFPs after each of the SFPs is plugged into each of the sockets. Each of the air-cooling heat dissipation devices removes a heat of each of the SFPs by a thermal convection to achieve a heat dissipation.

In recent years, with a transmission speed of a network switch increasing, power consumption of the network switch greatly increases. Under confinement of limited space, the air-cooling heat dissipation devices could not satisfy heat dissipation requirements. Because each of the sockets of the SFPs is independent, a contact surface provided for each of the air-cooling heat dissipation devices in contact with each of the SFP during each of the SFPs plugged into each of the sockets and the contact surface provided for each of the air-cooling heat dissipation devices in contact with each of the SFPs during each of the SFPs not plugged into the each of sockets are not on an identical level. When the air-cooling heat dissipation device is substituted with a liquid-cooling heat dissipation device with a great heat dissipation effect, a height of a contact surface on which a water-cooled plate of the identical liquid-cooling heat dissipation device is in contact with a heat source is fixed, so that the liquid-cooling heat dissipation device could not be applied to the contact surfaces corresponding to the sockets and having different heights. Therefore, how to provide a liquid-cooling heat dissipation device which could be disposed on a socket and could be adapted to objects with different heights, is a problem needed to be solved in the industry.

### BRIEF SUMMARY OF THE INVENTION

In view of the above, the primary objective of the present invention is to provide a liquid-cooling heat dissipation device which could be adapted to being in contact with objects with different heights and could achieve an effective heat dissipation.

The present invention provides a liquid-cooling heat dissipation device including a case, at least one floating heat spreader, and at least one retaining structure, wherein the case includes a liquid inlet and a liquid outlet. A chamber is formed in the case. The liquid inlet and the liquid outlet respectively communicate with the chamber. A main channel is formed in the chamber. Two ends of the main channel respectively communicate with the liquid inlet and the liquid outlet. At least one shallow groove is recessed into a surface of the case. A combining opening is formed in the least one shallow groove, wherein the combining opening communicates with the main channel. At least one retaining structure combining portion is disposed on the surface of the case corresponding to a periphery of the at least one shallow groove. The at least one floating heat spreader includes a base plate, an abutting plate, and a plurality of fins. The base plate of the at least one floating heat spreader is located in the at least one shallow groove. The base plate and an inner surface of the at least one shallow groove are spaced. The fins are connected to the base plate. The fins pass through the combining opening and extend into the main channel. A plurality of channels extending in an identical direction are formed between the fins. An extending direction of the channels is identical to an extending direction of the main channel located in a place in which the channels are located. The abutting plate is connected to the base plate and protrudes from the surface of the case. A seal ring is clamped between the base plate and an inner wall of the shallow groove located on a periphery of the combining opening. The seal ring is elastic and is compressible against the base plate. The seal ring surrounds the fins. The at least one retaining structure is combined with the at least one retaining structure combining portion and engages with a peripheral edge of the base plate to confine the base plate to the shallow groove.

With the aforementioned design, when the case of the liquid-cooling heat dissipation device is installed on a plurality of sockets and at least one small form-factor pluggable transceiver is plugged into at least one of the sockets and pushes up the at least one floating heat spreader, the at least one floating heat spreader moves towards the at least one shallow groove and compresses the seal ring and a restoring force generated by the seal ring is applied to the at least one floating heat spreader. In this way, the abutting plate of the at least one floating heat spreader could remain attaching to the small form-factor pluggable transceiver and the at least one small form-factor pluggable transceiver which has been plugged into at least one of the sockets could be well in contact with the abutting plate of the at least one floating heat spreader all the time, thereby achieving an effective heat dissipation. When the at least one small form-factor pluggable transceiver is unplugged from the at least one socket, the at least one small form-factor pluggable transceiver is subjected to the restoring force of the seal ring and returns to an original position.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a perspective view of the liquid-cooling heat dissipation device according to a first embodiment of the present invention;

FIG. 2 is a top view of the liquid-cooling heat dissipation device according to the first embodiment of the present invention;

FIG. 3 is a side view of the liquid-cooling heat dissipation device according to the first embodiment of the present invention;

FIG. 4 is an exploded view of the liquid-cooling heat dissipation device according to the first embodiment of the present invention;

FIG. 5 is a sectional view along the 5-5 line in FIG. 3;

FIG. 6 is a sectional view along the 6-6 line in FIG. 2;

FIG. 7 is a sectional view along the 7-7 line in FIG. 2;

FIG. 8 is a schematic view of the liquid-cooling heat dissipation device according to the first embodiment of the present invention, showing that the floating heat spreader is pushed up by the small form-factor pluggable transceiver having been plugged into the socket;

FIG. 9 is a perspective view of the liquid-cooling heat dissipation device according to a second embodiment of the present invention;

FIG. 10 is a top view of the liquid-cooling heat dissipation device according to the second embodiment of the present invention;

FIG. 11 is a side view of the liquid-cooling heat dissipation device according to the second embodiment of the present invention;

FIG. 12 is an exploded view of the liquid-cooling heat dissipation device according to the second embodiment of the present invention;

FIG. 13 is a sectional view along the 13-13 line in FIG. 11;

FIG. 14 is a sectional view along the 14-14 line in FIG. 10; and

FIG. 15 is a schematic view of the liquid-cooling heat dissipation device according to the second embodiment of the present invention, showing that the floating heat spreader is pushed up by the small form-factor pluggable transceiver having been plugged into the socket.

### DETAILED DESCRIPTION OF THE INVENTION

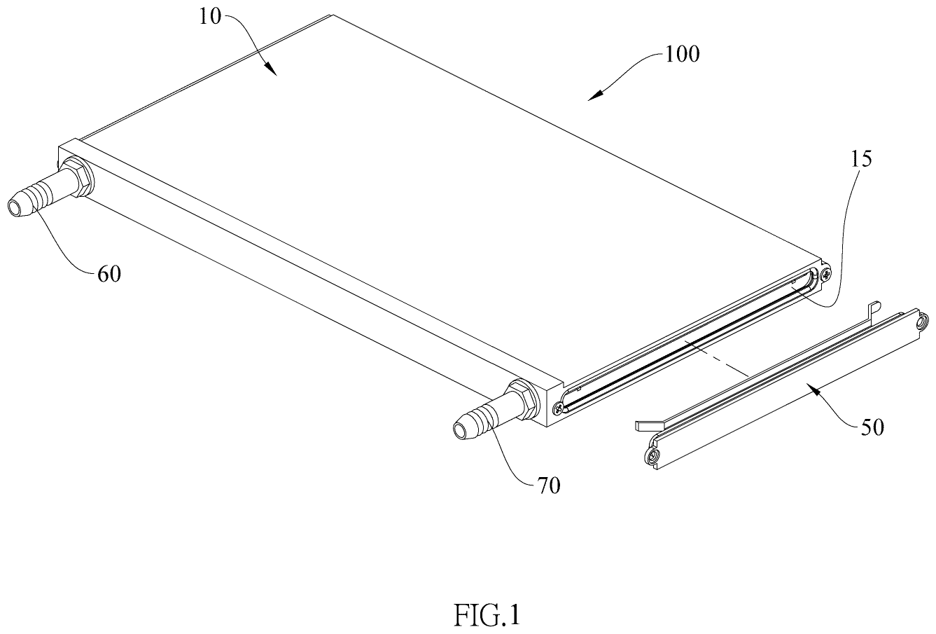

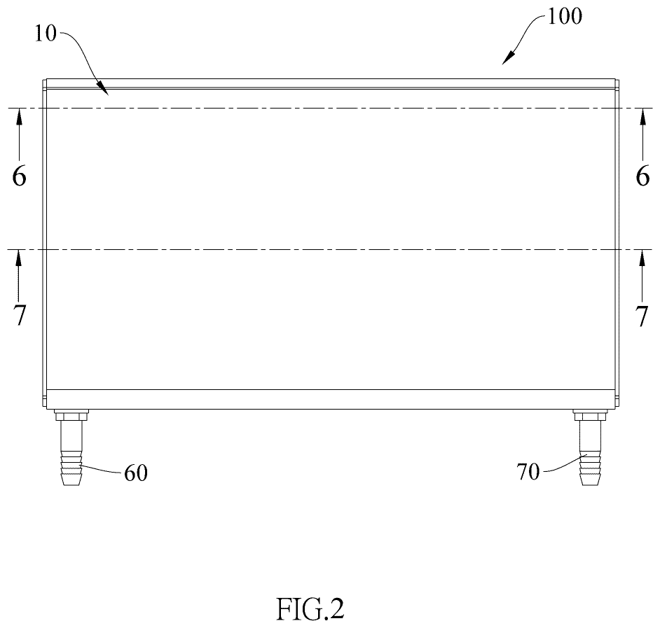

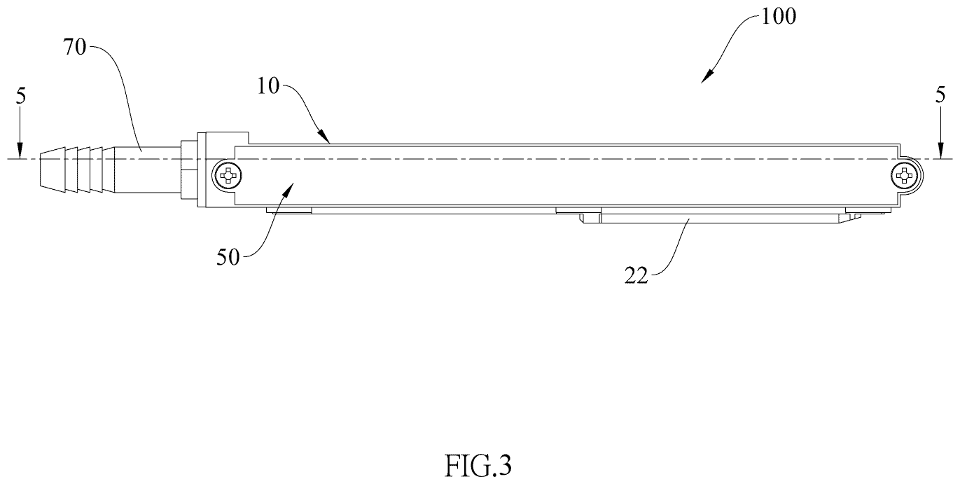

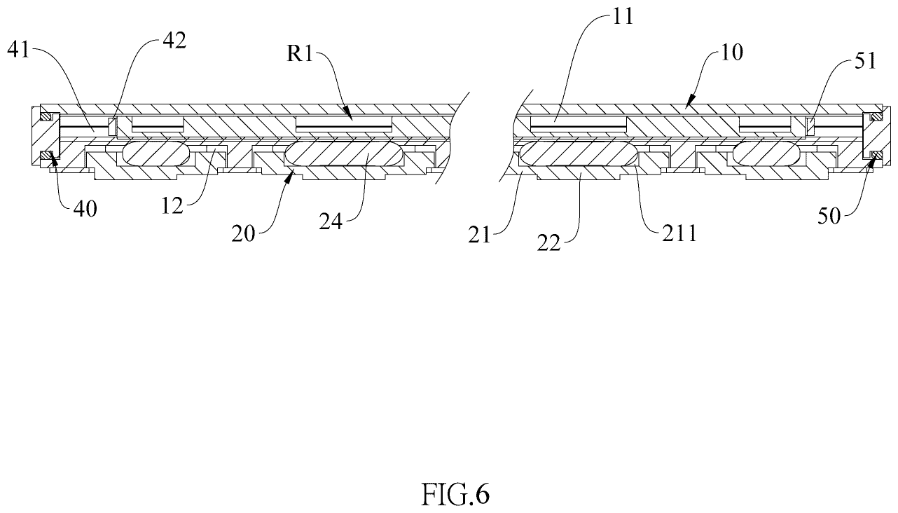

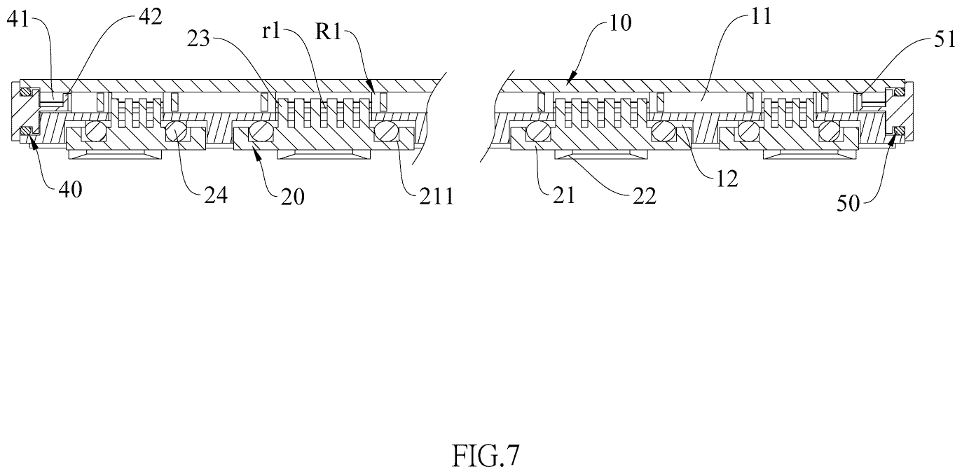

A liquid-cooling heat dissipation device 100 according to a first embodiment of the present invention is illustrated in FIG. 1 to FIG. 8 and includes a case 10, six floating heat spreaders 20, and six retaining structures 30, wherein a number of the retaining structures 30 corresponds to a number of the floating heat spreaders 20.

Referring to FIG. 1 to FIG. 5, the case 10 is a rectangular and flat case and has a front side, a back side, a left side, a right side, a top side, a bottom side in terms of direction. A chamber 11 is formed in the case 10. A main channel R1 is formed in the chamber 11. The front side of the case 10 and the back side of the case 10 respectively have a first wall 16 and a second wall 17. A left side of the second wall 17 and a right side of the second wall 17 respectively have a liquid inlet 171 and a liquid outlet 172, wherein the liquid inlet 171 and the liquid outlet 172 respectively communicate with the chamber 11. An inlet connector 60 is combined with the liquid inlet 171. An outlet connector 70 is combined with the liquid outlet 172. The left side of the case 10 and the right side of the case 10 respectively have a first side opening 14 and a second side opening 15, wherein the first side opening 14 and the second side opening 15 are respectively combined with a first side cover 40 and a second side cover 50 in a sealed way. Six shallow grooves 12 of which a number corresponds to the number of the floating heat spreaders 20 are recessed into a surface of the bottom side of the case 10. The six shallow grooves 12 are spaced along a right-left direction. A combining opening 121 is formed in a middle of an inner wall of each of the six shallow grooves 12, wherein the combining opening 121 communicates with the main channel R1. A retaining structure combining portion 13 is disposed on the surface of the bottom side of the case 10 corresponding to a periphery of each of the six shallow grooves 12.

The first side cover 40 has a first pipe 41. A first cover 411 is formed at an end of the first pipe 41. A first confluence opening 412 is formed in the first cover 411. The first cover 411 covers the liquid inlet 171. The first confluence opening 412 communicates with the first pipe 41 and the liquid inlet 171. An end of the main channel R1 communicates with the first pipe 41 and another end of the main channel R1 communicates with the liquid outlet 172.

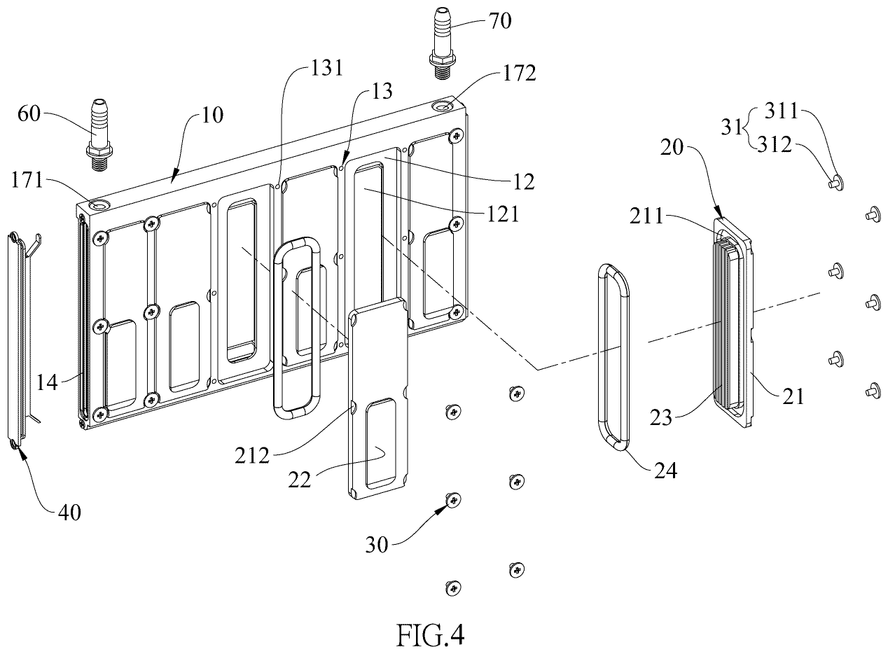

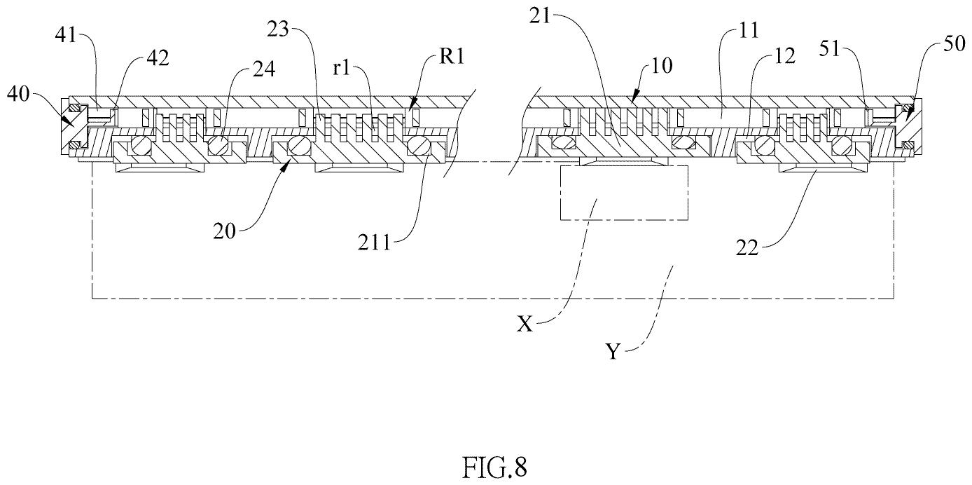

Referring to FIG. 4 to FIG. 7, the six floating heat spreaders 20 are arranged along the right-left direction and are disposed in the six shallow grooves 12 of the case 10. Each of the six floating heat spreaders 20 corresponds to each of the six shallow grooves 12. Each of the six floating heat spreaders 20 includes a base plate 21, an abutting plate 22, and a plurality of fins 23. The base plate 21 of each of the six floating heat spreaders 20 is located in each of the six shallow grooves 12. A periphery of a surface of each of the six base plates 21 facing each of the six shallow grooves 12 has a circular groove 211. A plurality of recesses 212 are formed on another surface of each of the six base plates 21 away from each of the six shallow grooves 12, wherein the recesses 212 of each of the six base plates 21 are spaced around a peripheral edge of each of the six base plates 21. A side of each of the fins 23 of each of the six floating heat spreaders 20 is connected to the base plate 21 of each of the six floating heat spreaders 20 and is located within a range in which the groove 211 of each of the six floating heat spreaders 20 surrounds. Another side of each of the fins 23 passes through each of the six combining openings 121 and extends into the main channel R1. A plurality of channels r1 extending in an identical direction are formed between the fins 23. An extending direction of each of the channels r1 is identical to an extending direction of the main channel R1 in a place in which the channels r1 are located. The abutting plate 22 is connected to the surface of the base plate 21 away from the shallow groove 12 and protrudes from the surface of the bottom side of the case 10. Referring to FIG. 8, the abutting plate 22 is adapted to abutting against a small form-factor pluggable transceiver X. Referring to FIG. 4 to FIG. 7, a seal ring 24 is clamped between the base plate 21 of each of the six floating heat spreaders 20 and an inner surface of each of the six shallow grooves 12 and surrounds the fins 23. A side of the seal ring 24 of each of the six floating heat spreaders 20 surrounds a periphery of each of the six combining openings 121. Another side of the seal ring 24 of each of the six floating heat spreaders 20 fits in the groove 211 of each of the six floating heat spreaders 20. The seal ring 24 of each of the six floating heat spreaders 20 is elastic and compressible. When each of the six floating heat spreaders 20 moves towards each of the six shallow grooves 12, the base plate 21 of each of the six floating heat spreaders 20 compresses the seal ring 24 of each of the six floating heat spreaders 20.

The six retaining structures 30 are respectively combined with each of the six retaining structure combining portions 13. In the current preferable embodiment, each of the six retaining structures 30 includes a plurality of bolts 31, wherein each of the bolts 31 includes a body portion 312 and a head portion 311. Each of the six retaining structure combining portions 13 includes a plurality of screw holes 131, wherein the screw holes 131 are disposed on the surface of the bottom side of the case 10 and are spaced around each of the six shallow grooves 12. The bolts 31 are respectively screwed into the screw holes 131 by the body portions 312 and engage with the recesses 212 of the six base plate 21 by the head portions 311. In this way, because each of the six retaining structures 30 confines each of the six base plates 21 to each of the six shallow grooves 12, the base plate 21 of each of the six floating heat spreaders 20 could be lifted or lowered in each of the six shallow grooves 12 within a range confined by each of the six retaining structures 30. In other embodiments, each of the six retaining structures 30 could be a buckle combined with each of the retaining structure combining portions 13 and surrounding the periphery of each of the six base plates 21. Each of the six retaining structures 30 has a hook portion to hook a peripheral edge of each of the six base plates 21 and confine a position of each of the six base plates 21 to each of the six shallow grooves 12, so that the base plate 21 of each of the six floating heat spreaders 20 could be lifted or lowered in each of the six shallow grooves 12 within the range confined by each of the six retaining structures 30.

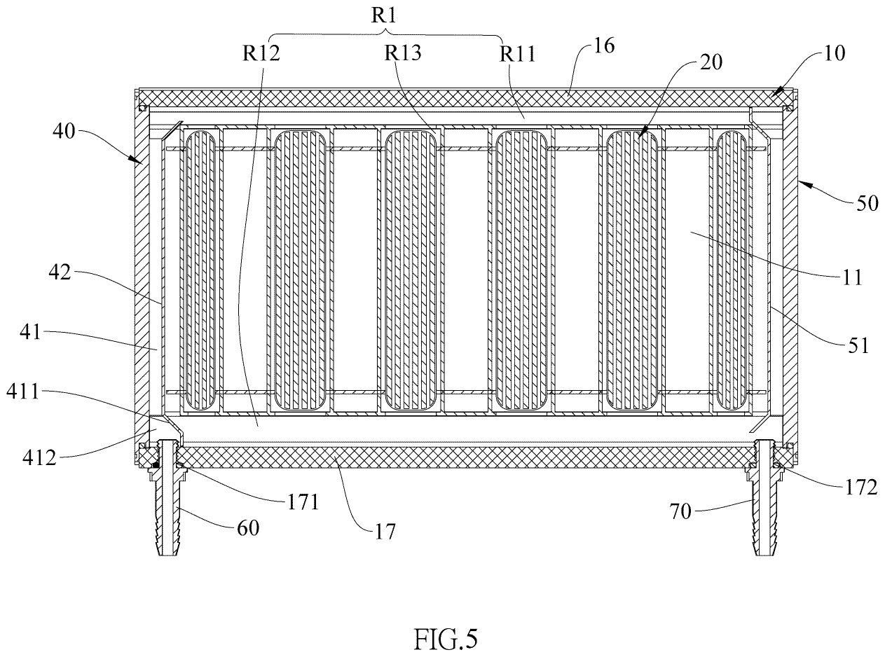

Referring to FIG. 5, the first side cover 40 includes a first side wall 42. The second side cover 50 includes a second side wall 51. The first side wall 42 and the second side wall 51 face each other. The first side wall 42, the second side wall 51, the first wall 16, and the second wall 17 surround around the chamber 11. The main channel R1 includes a first section R11, a second section R12, and six third sections R13 of which a number corresponds to a number of the six combining openings 121, wherein the first section R11 communicates with the first pipe 41 and is adjacently connected to an inner surface of the first wall 16. The second section R12 communicates with the liquid outlet 172 and is adjacently connected to an inner surface of the second wall 17. The first section R11 is parallel to the second section R12. The six third sections R13 are spaced. Each of the six third sections R13 is perpendicular to the first section R11 and the second section R12. The first section R11 communicates with the second section R12 through the six third sections R13. Each of the six third sections R13 communicates with each of the six combining openings 121. The fins 23 of each of the six floating heat spreaders 20 extend into each of the six third sections R13. The extending direction of each of the channels r1 of each of the six floating heat spreaders 20 is identical to an extending direction of each of the third sections R13.

When the liquid-cooling heat dissipation device 100 of the first embodiment is used, the case 10 is filled with a cooling liquid flowing in the main channel R1. In the below description, a channel route in which the cooling liquid enters the liquid-cooling heat dissipation device 100 is illustrated. After the cooling liquid enters the inlet connector 60, the cooling liquid passes through the liquid inlet 171 and flows into the first confluence opening 412. Subsequently, by the guidance of the first cover 411, the cooling liquid enters the first pipe 41 and flows into the first section R11 of the main channel R1. Subsequently, the cooling liquid flows into the six third sections R13 of the main channel R1 and then the cooling liquid having flowed into the six third sections R13 passes through the channels r1 located between the fins 23 and removes a heat of each of the six floating heat spreaders 20, so that each of the six floating heat spreaders 20 could be cooled down. Eventually, the cooling liquid enters the second section R12 of the main channel R1, passes through the liquid outlet 172, and is discharged from the case 10 through the outlet connector 70.

When the liquid-cooling heat dissipation device 100 of the first embodiment is used, the liquid-cooling heat dissipation device 100 is disposed on six sockets Y which a communication device has with a number of the sockets Y corresponding to the number of the floating heat spreaders 20; each of the six floating heat spreaders 20 corresponds to each of the six sockets Y. The six sockets Y are spaced along the right-left direction. Each of the six sockets Y has a jack, wherein the jack of each of the six sockets Y is provided for the small form-factor pluggable transceiver X hot-plugged into the jack of each of the six sockets Y or hot-unplugged from the jack of each of the six sockets Y. The abutting plate 22 of each of the six floating heat spreaders 20 extends into a top side of each of the six sockets Y.

Referring to FIG. 8, when the small form-factor pluggable transceiver X is plugged into the jack of each of the six sockets Y, the small form-factor pluggable transceiver X abuts against the abutting plate 22 of the corresponding floating heat spreader 20, the corresponding floating heat spreader 20 is pushed up, the seal ring 24 located between the floating heat spreader 20 and the case 10 is compressed. A restoring force generated by the seal ring 24 is applied to the floating heat spreader 20, so that the floating heat spreader 20 could remain attaching to the small form-factor pluggable transceiver X.

By the small form-factor pluggable transceiver X being in contact with the abutting plate 22 of the corresponding floating heat spreader 20, a heat generated during an operation of the small form-factor pluggable transceiver X is conducted to the cooling liquid located in the chamber 11 through the fins 23 of the corresponding floating heat spreader 20. With a circulation process that the cooling liquid flows into the case 10 through the liquid inlet 171 and is discharged from the case 10 through the liquid outlet 172, the heat conducted to the cooling liquid is removed, so that the small form-factor pluggable transceiver X in contact with the floating heat spreader 20 could be cooled down.

When the small form-factor pluggable transceiver X is unplugged from the socket Y, the floating heat spreader 20 corresponding to the socket Y is no longer pushed up by the small form-factor pluggable transceiver X, so that the floating heat spreader 20 subjected to the restoring force of the seal ring 24 would return to an original position in which the floating heat spreader 20 is not pushed up by the small form-factor pluggable transceiver X. During each of the six floating heat spreaders 20 lifting or declining, because a maximum distance between the base plate 21 and the inner surface of the shallow groove 12 which are confined by the retaining structure 30 is less than a cross-sectional diameter of the seal ring 24, the seal ring 24 could seal between the base plate 21 and the shallow groove 12 to prevent leakage.

In the first embodiment according to the present invention, the number of the floating heat spreaders 20 of the liquid-cooling heat dissipation device 100 is six. In other embodiments, the number of the floating heat spreader 20 of the liquid-cooling heat dissipation device 100 could be, but not limited to, at least one and correspond to the number of the socket Y; the number of the combining opening 121, the number of the retaining structure 30, a number of the seal ring 24, and the number of the third section R13 correspond to the number of the floating heat spreader 20. In addition to rectangular shape, the case 10 could be a case in another shape. The first section R11 could be not parallel to the second section R12, and each of the six third sections R13 is not limited to being perpendicular to the first section R11 and the second section R12. A position of the liquid outlet 172 and a position of the liquid inlet 171 could be adjusted based on the requirement. The surface of each of the six base plates 21 facing each of the six shallow grooves 12 could be not connected to the fins 23. The way that the six retaining structure combining portions 13 correspond to the six retaining structures 30 is not limited to the screw holes 131 cooperating with the bolts 31, and the six retaining structure combining portions 13 could work with the six retaining structures 30 in another way.

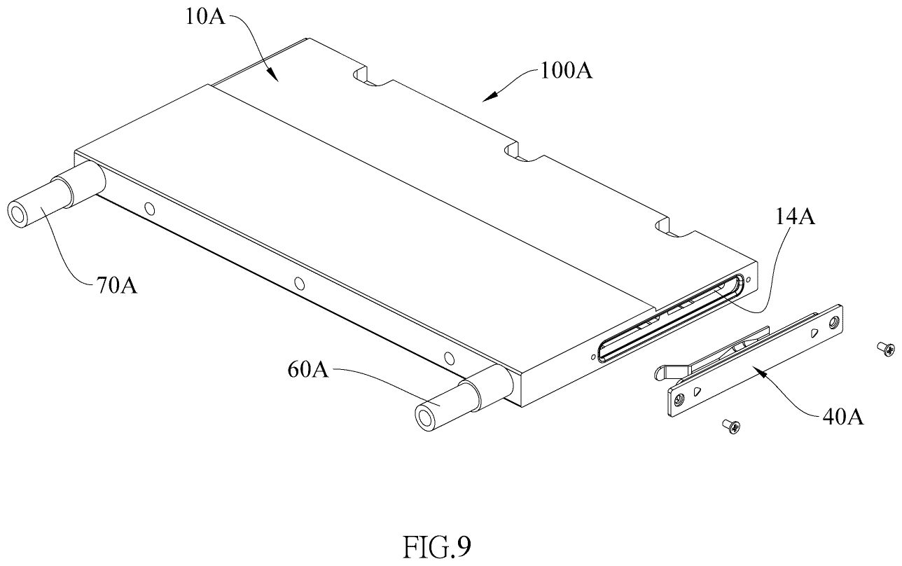

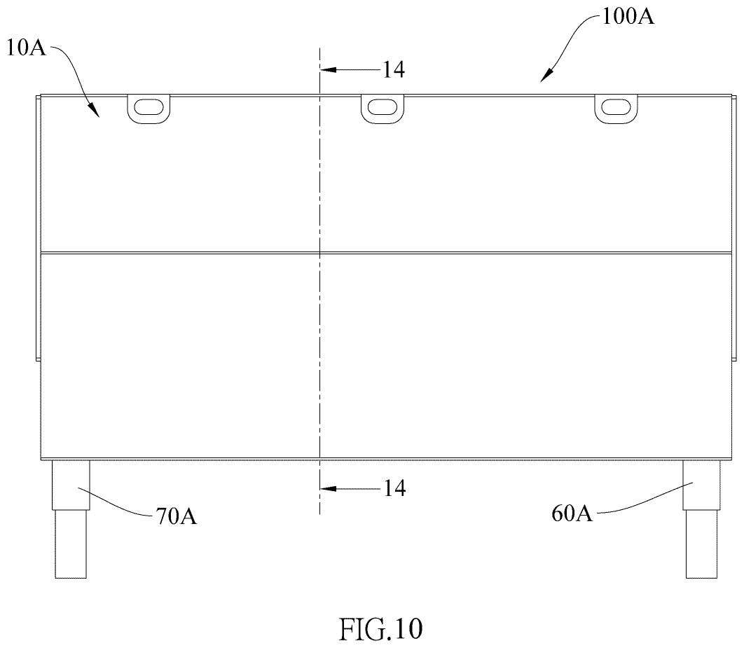

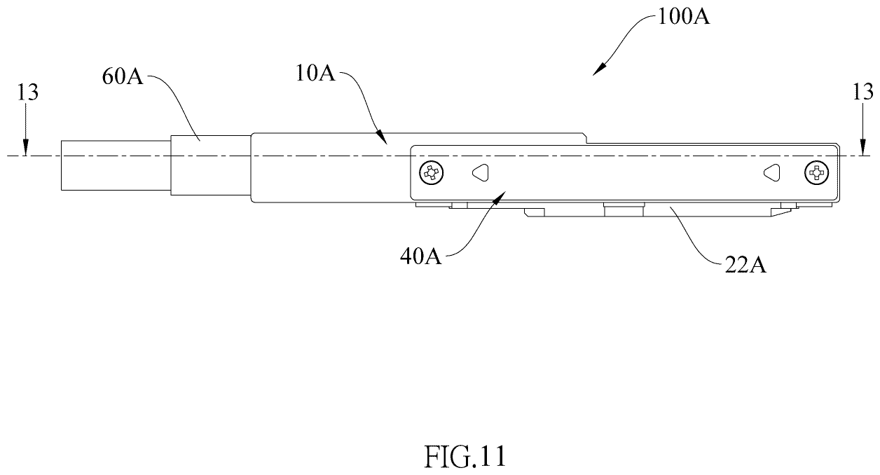

A liquid-cooling heat dissipation device 100A according to a second embodiment of the present invention is illustrated in FIG. 9 to FIG. 15 and includes a case 10A, six floating heat spreaders 20A, and six retaining structures 30A of which a number corresponds to a number of the six floating heat spreaders 20A.

Referring to FIG. 9 to FIG. 13, the case 10A is a rectangular and flat case and has a front side, a back side, a left side, a right side, a top side, a bottom side in terms of direction. A chamber 11A is formed in the case 10A. A main channel R2 is formed in the chamber 11A. The front side of the case 10A and the back side of the case 10A respectively have a first wall 16A and a second wall 17A. Two partitions 18 are provided between the first wall 16A and the second wall 17A and are arranged in parallel. Each of the two partitions 18 is parallel to the first wall 16A and the second wall 17A. A left side of the second wall 17A and a right side of the second wall 17A respectively have a liquid outlet 172A and a liquid inlet 171A, wherein the liquid outlet 172A and the liquid inlet 171A respectively communicate with the chamber 11A. An inlet connector 60A is combined with the liquid inlet 171A. An outlet connector 70A is combined with the liquid outlet 172A. The left side of the case 10A and the right side of the case 10A respectively have a second side opening 15A and a first side opening 14A, wherein the second side opening 15A and the first side opening 14A are respectively combined with a second side cover 50A and a first side cover 40A in a sealed way. Six shallow grooves 12A of which a number corresponds to the number of the floating heat spreaders 20A are recessed into a surface of the bottom side of the case 10A. The six shallow grooves 12A are spaced along a right-left direction. A combining opening 121A is formed in a middle of an inner wall of each of the six shallow grooves 12A, wherein the combining opening 121A of each of the six shallow grooves 12A communicates with the main channel R2. A retaining structure combining portion 13A is disposed on the surface of the bottom side of the case 10A corresponding to a periphery of each of the six shallow grooves 12A.

The first side cover 40A has a first pipe 41A. A first cover 411A is formed at an end of the first pipe 41A. A first confluence opening 412A is formed in the first cover 411A. The first cover 411A covers the liquid inlet 171A. The first confluence opening 412A communicates with the first pipe 41A and the liquid inlet 171A. An end of the main channel R2 communicates with the first pipe 41A and another end of the main channel R2 communicates with the liquid outlet 172A.

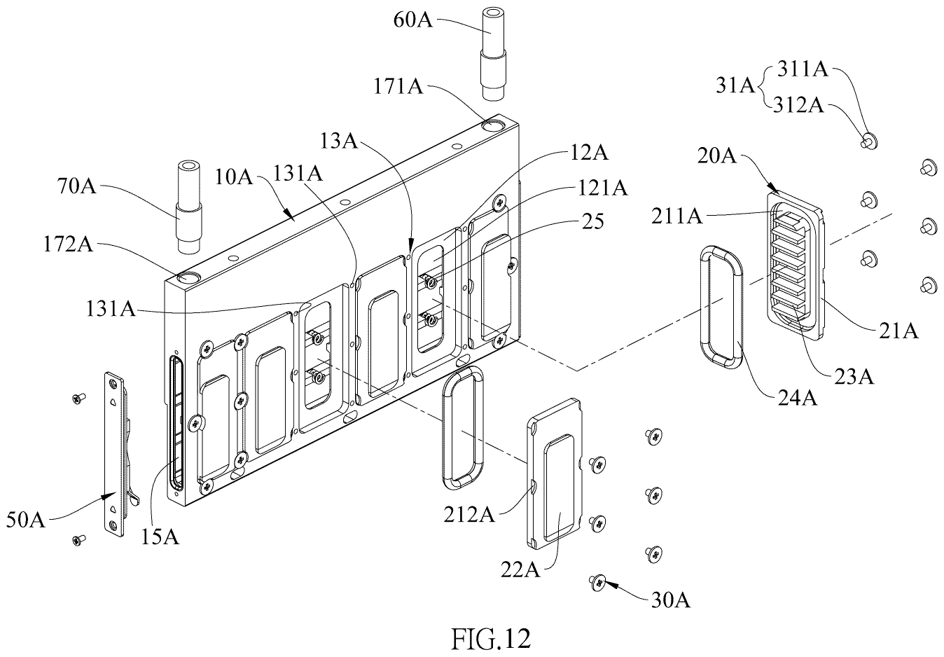

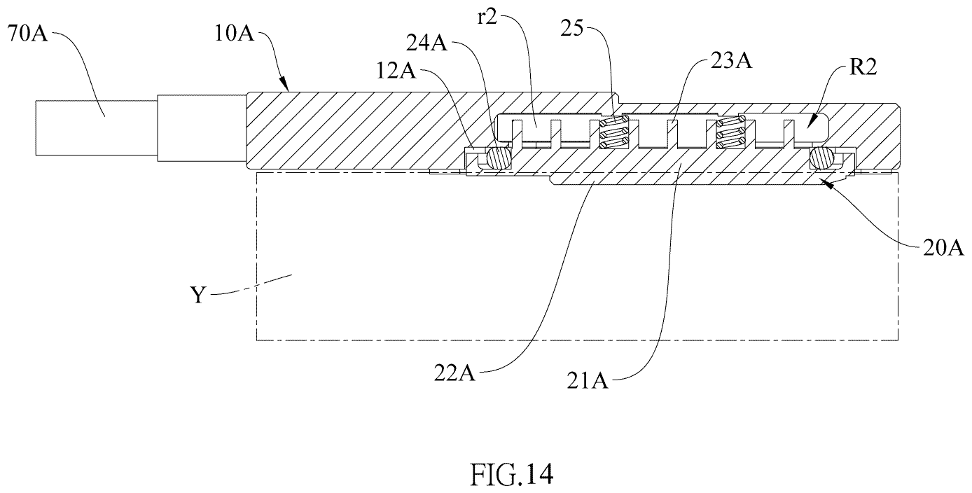

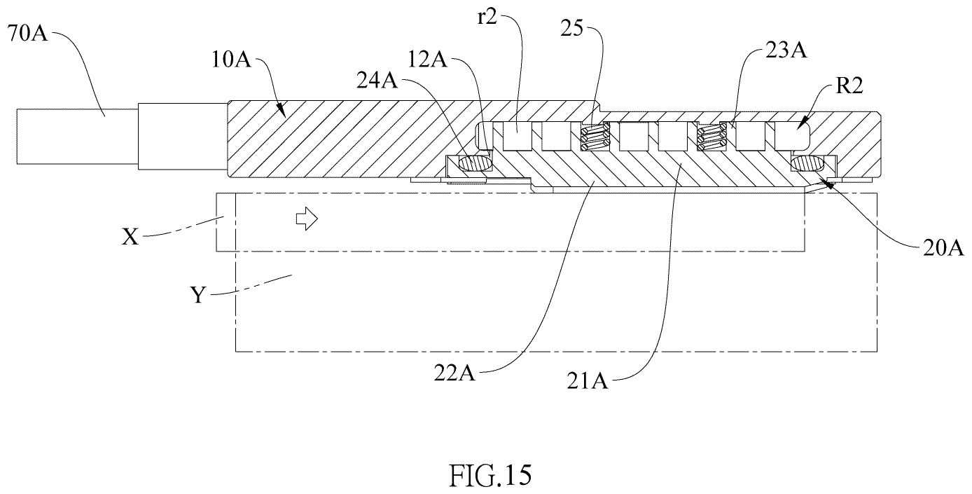

Referring to FIG. 12 and FIG. 14, the six floating heat spreaders 20A are arranged along the right-left direction and are disposed in the six shallow grooves 12A of the case 10A. Each of the six floating heat spreaders 20A corresponds to each of the six shallow grooves 12A. Each of the six floating heat spreaders 20A includes a base plate 21A, an abutting plate 22A, and a plurality of fins 23A. The base plate 21A of each of the six floating heat spreaders 20A is located in each of the six shallow grooves 12A. A periphery of a surface of each of the six base plates 21A facing each of the six shallow grooves 12A has a circular groove 211A. A plurality of recesses 212A are formed on another surface of each of the six base plates 21A away from each of the six shallow grooves 12A, wherein the recesses 212A of each of the six base plates 21A are spaced around a peripheral edge of each of the six base plates 21A. A side of each of the fins 23A of each of the six floating heat spreaders 20A is connected to the base plate 21A of each of the six floating heat spreaders 20A and is located within a range in which the groove 211A of each of the six base plates 21A surrounds. Another side of each of the fins 23A of each of the six floating heat spreaders 20A passes through each of the six combining openings 121A and extends into the main channel R2. A plurality of channels r2 extending in an identical direction are formed between the fins 23A. An extending direction of each of the channels r2 is identical to an extending direction of the main channel R2 located in a place in which the channels r2 are located. The abutting plate 22A is connected to the another surface of the base plate 21A away from the shallow groove 12A and protrudes from the surface of the bottom side of the cases 10A. Referring to FIG. 14 and FIG. 15, the abutting plate 22A is adapted to abutting against the small form-factor pluggable transceiver X. Referring to FIG. 12 to FIG. 14, the case 10A has twelve springs 25. An end of each of the twelve springs 25 abuts against an inner surface of the top side of the case 10A, and another end of each of the twelve springs 25 abuts against the corresponding floating heat spreader 20A. Any two springs 25 of the twelve springs 25 correspond to each of the six floating heat spreaders 20A. A seal ring 24A is clamped between the base plate 21A of each of the six floating heat spreaders 20A and an inner surface of each of the six shallow grooves 12A and surrounds the fins 23A. A side of the seal ring 24A of each of the six floating heat spreaders 20A surrounds a periphery of each of the six combining openings 121A. Another side of the seal ring 24A of each of the six floating heat spreaders 20A fits in the groove 211A of each of the six floating heat spreaders 20A. Each of the twelve springs 25 and the seal ring 24A of each of the six floating heat spreaders 20A are elastic and compressible. When each of the six floating heat spreaders 20A moves towards each of the six shallow grooves 12A, each of the six base plates 21A compresses each of the twelve springs 25 and each of the six seal rings 24A.

Each of the six retaining structures 30A is combined with each of the six retaining structure combining portions 13A and includes a plurality of bolts 31A, wherein each of the bolts 31A includes a body portion 312A and a head portion 311A. Each of the six retaining structure combining portions 13A includes a plurality of screw holes 131A, wherein the screw holes 131A of each of the six retaining structure combining portions 13A are disposed on the surface of the bottom side of the case 10A and are spaced around each of the six shallow grooves 12A. The bolts 31A are respectively screwed into the screw holes 131A by the body portions 312A and engage with the recesses 212A of each of the six base plates 21A by the head portions 311A. In this way, because each of the six retaining structures 30A could confine each of the six base plates 21A to each of the six shallow grooves 12A, the base plate 21A of each of the six floating heat spreaders 20A could be lifted or lowered in each of the six shallow grooves 12A within a ranged confined by each of the six retaining structures 30A.

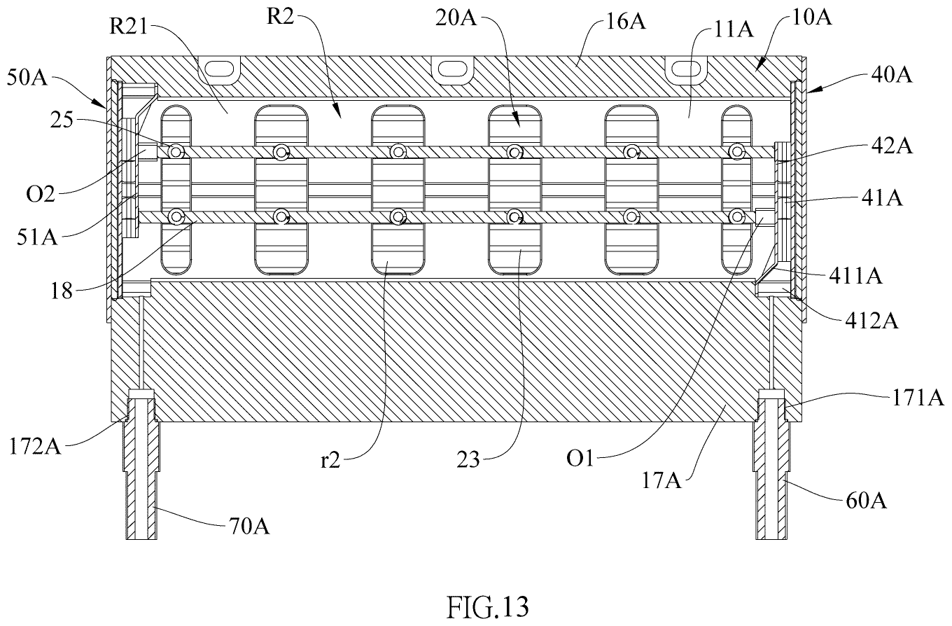

Referring to FIG. 13, the first side cover 40A has a first side wall 42A. The second side cover 50A includes a second side wall 51A. The first side wall 42A and the second side wall 51A face each other. The first side wall 42A, the second side wall 51A, the first wall 16A, and the second wall 17A surround around the chamber 11A. The two partitions 18 are located between the first wall 16A and the second wall 17A and divide the main channel R2 into three flowing sections R21. The two partitions 18 are sequentially arranged from the second wall 17A to the first wall 16A and contain an odd-numbered partition 18 and an even-numbered partition 18. A first opening O1 is formed between an end of the odd-numbered partition 18 and the first side wall 42A, and another end of the odd-numbered partition 18 abuts against the second side wall 51A. A second opening O2 is formed between an end of the even-numbered partition 18 and the second side wall 51A and another end of the even-numbered partition 18 abuts against the first side wall 42A. The first opening O1 and the second opening O2 are sequentially disposed in a staggered arrangement. Any two adjacent flowing sections R21 of the three flowing sections R21 communicate with each other through the first opening O1 or the second opening O2. Each of the six combining openings 121A penetrates through the three flowing sections R21 and communicates with the three flowing sections R21. The fins 23A of each of the six floating heat spreaders 20A extend into the three flowing sections R21. The extending direction of each of the channels r2 of each of the six floating heat spreaders 20A is identical to an extending direction of each of the three flowing sections R21.

When the liquid-cooling heat dissipation device 100A of the second embodiment is used, the case 10A is filled with a cooling liquid flowing in the main channel R2. In the below description, a channel route in which the cooling liquid enters the liquid-cooling heat dissipation device 100A is illustrated. After the cooling liquid enters the inlet connector 60A, the cooling liquid passes through liquid inlet 171A and flows into the first confluence opening 412A. Subsequently, by the guidance of the first cover 411A, the cooling liquid enters the first pipe 41A and flows into the flowing section R21 of the main channel R2 adjacently connected to the first wall 16A. Subsequently, the cooling liquid passes through the second opening O2, flows into the flowing section R21 between the two partitions 18, passes through the first opening O1, and flows into the flowing section R21 adjacently connected to the second wall 17A. Eventually, the cooling liquid passes through the liquid outlet 172A and is discharged from the case 10A through the outlet connector 70A. When the cooling liquid flows into the three flowing sections R21, the cooling liquid passes through the channels r2 formed between the fins 23A and removes a heat of each of the six floating heat spreaders 20A, so that each of the floating heat spreader 20A could be cooled down.

When the liquid-cooling heat dissipation device 100A of the second embodiment is used, the liquid-cooling heat dissipation device 100A is disposed on the six sockets Y which the communication device has with the number of the sockets Y corresponding to the number of the floating heat spreaders 20A; each of the six floating heat spreaders 20A corresponds to each of the six sockets Y. The six sockets Y are spaced along the right-left direction. Each of the six sockets Y has the jack, wherein the jack of each of the six sockets Y is provided for the small form-factor pluggable transceiver X hot-plugged into the jack of each of the six sockets Y and hot-unplugged from the jack of each of the six sockets Y. The abutting plate 22A of each of the six floating heat spreaders 20A extends into the top side of each of the six sockets Y.

Referring to FIG. 15, when the small form-factor pluggable transceiver X is plugged into the jack of each of the six sockets Y, the small form-factor pluggable transceiver X abuts against the abutting plate 22A of the corresponding floating heat spreader 20A, the corresponding floating heat spreader 20A is pushed up, the seal ring 24A located between the floating heat spreader 20A and the case 10A and the two springs 25 are compressed, and a restoring force generated by the seal ring 24A and the two springs 25 is applied to the floating heat spreader 20A, so that the floating heat spreader 20A could remain attaching to the small form-factor pluggable transceiver X.

By the small form-factor pluggable transceiver X being in contact with the abutting plate 22A of each of the corresponding floating heat spreader 20A, the heat generated during an operation of the small form-factor pluggable transceiver X is conducted to the cooling liquid in the chamber 11A through the fins 23A of the corresponding floating heat spreader 20A. With a circulation process that the cooling liquid flows into the case 10A through the liquid inlet 171A and is discharged from the case 10A through the liquid outlet 172A, the heat conducted to the cooling liquid is removed, so that the small form-factor pluggable transceiver X in contact with the floating heat spreader 20A could be cooled down.

When the small form-factor pluggable transceiver X is unplugged from the socket Y, the floating heat spreader 20A corresponding the socket Y is no longer pushed up by the small form-factor pluggable transceiver X, so that the floating heat spreader 20A subjected to the restoring force of the seal ring 24A and the two springs 25 would return to an original position in which the floating heat spreader 20A is not pushed up by the small form-factor pluggable transceiver X. During each of the six floating heat spreaders 20A being lifted or lowered, because a maximum distance between the base plate 21A and the inner surface of the shallow groove 12A which are confined by the retaining structure 30A is less than a cross-sectional diameter of the seal ring 24A, the seal ring 24A could seal between the base plate 21A and the shallow groove 12A to prevent leakage.

In the second embodiment according to the present invention, the number of the floating heat spreaders 20A of the liquid-cooling heat dissipation device 100A is six. In other embodiments, the number of the floating heat spreader 20A of the liquid-cooling heat dissipation device 100A could be, but not limited to, at least one and correspond to the number of the socket Y; a number of the combining opening 121A, the number of the retaining structure 30A, a number of the seal ring 24A, and the number of the spring 25 correspond to the number of the floating heat spreader 20A. In addition to the rectangular shape, the case 10A could be a case in another shape. The number of the flowing sections R21 could be more than three. A position of the liquid outlet 172A and a position of the liquid inlet 171A could be adjusted based on the requirement. The surface of each of the six base plates 21A facing each of the six shallow grooves 12A could be not connected to the fins 23A. The way that the six retaining structure combining portions 13A correspond to the six retaining structures 30A is not limited to the screw holes 131A cooperating with the bolts 31A, and the six retaining structure combining portions 13A could work with the six retaining structures 30A in another way.

It must be pointed out that the embodiments described above are only some preferred embodiments of the present invention. All equivalent structures which employ the concepts disclosed in this specification and the appended claims should fall within the scope of the present invention.

What is claimed is:

1. A liquid-cooling heat dissipation device, comprising:
a case comprising a liquid inlet and a liquid outlet, wherein a chamber is formed in the case; the liquid inlet and the liquid outlet respectively communicate with the chamber; a main channel is formed in the chamber; two ends of the main channel respectively communicate with the liquid inlet and the liquid outlet; at least one shallow groove is recessed into a surface of a side of the case; a combining opening is formed in the at least one shallow groove, wherein the combining opening communicates with the main channel; at least one retaining structure combining portion is disposed on the surface of the case corresponding to a periphery of the at least one shallow groove;
at least one floating heat spreader comprising a base plate, an abutting plate, and a plurality of fins, wherein the base plate of the at least one floating heat spreader is located in the at least one shallow groove; the base plate and an inner surface of the at least one shallow groove are spaced; the plurality of fins are connected to the base plate; the plurality of fins pass through the combining opening and extend into the main channel; a plurality of channels extending in an identical direction are formed between the plurality of fins; an extending direction of each of the plurality of channels is identical to an extending direction of the main channel located in a place in which the plurality of channels are located; the abutting plate is connected to the base plate and protrudes from the surface of the case; a seal ring is clamped between the base plate of the at least one floating heat spreader and an inner wall of the at least one shallow groove located on a periphery of the combining opening; the seal ring is elastic and is compressible against the base plate; the seal ring surrounds the plurality of fins; and
at least one retaining structure combined with the at least one retaining structure combining portion and engaging with a peripheral edge of the base plate of the at least one floating heat spreader to confine the base plate of the at least one floating heat spreader to the at least one shallow groove.

2. The liquid-cooling heat dissipation device as claimed in claim 1, wherein one of two opposite sides of the case has a first side opening and the other side of the case has a second side opening; the first side opening is combined with a first side cover and the second side opening is combined with a second side cover; the first side cover has a first pipe; a first cover is formed at an end of the first pipe; a first confluence opening is formed in the first cover; the first cover covers the liquid inlet; the first confluence opening communicates with the first pipe and the liquid inlet; another end of the first pipe communicates with the main channel.

3. The liquid-cooling heat dissipation device as claimed in claim 2, wherein the first side cover comprises a first side wall; the second side cover comprises a second side wall; the first side wall and the second side wall face each other.

4. The liquid-cooling heat dissipation device as claimed in claim 3, wherein the at least one shallow groove comprises a plurality of shallow grooves; the at least one floating heat spreader comprises a plurality of floating heat spreaders; the at least one retaining structure comprises a plurality of retaining structures; an inner portion of the case has a first wall and a second wall; an inner surface of the first wall and an inner surface of the second wall are respectively located on two opposite sides of the chamber; the first side wall, the second side wall, the first wall, and the second wall surround around the chamber; two sides of the second wall respectively have the liquid inlet and the liquid outlet; the main channel comprises a first section, a second section, and a plurality of third sections, wherein the first section communicates with the first pipe and is adjacently connected to the inner surface of the first wall; the second section communicates with the liquid outlet and is adjacently connected to the inner surface of the second wall; the first section is parallel to the second section; the plurality of third sections are spaced; each of the plurality of third sections is perpendicular to the first section and the second section; the first section communicates with the second section through the plurality of third sections; the combining opening of each of the plurality of shallow grooves communicates with each of the plurality of third sections; the plurality of fins of each of the plurality of floating heat spreaders extend into each of the plurality of third sections.

5. The liquid-cooling heat dissipation device as claimed in claim 3, wherein an inner portion of the case has a first wall and a second wall; an inner surface of the first wall and an inner surface of the second wall are respectively located on two opposite sides of the chamber; an end of the main channel communicates with the first pipe and another end of the main channel communicates with the liquid outlet; the inner portion of the case has a plurality of partitions, wherein the plurality of partitions divide the main channel into a plurality of flowing sections; the plurality of partitions arranged in an order from the second wall to the first wall contain at least one odd-numbered partition and at least one even-numbered partition; a first opening is formed between an end of the at least one odd-numbered partition and the first side wall, and another end of the at least one odd-numbered partition abuts against the second side wall; a second opening is formed between an end of the at least one even-numbered partition and the second side wall, and another end of the at least one even-numbered partition abuts against the first side wall; the first opening and the second opening are sequentially disposed in a staggered arrangement; any two adjacent flowing sections of the plurality of adjacent flowing sections communicate with each another through the first opening or the second opening.

6. The liquid-cooling heat dissipation device as claimed in claim 1, further comprising an outlet connector and an inlet connector, wherein the outlet connector is combined with the liquid outlet; the inlet connector is combined with the liquid inlet.

7. The liquid-cooling heat dissipation device as claimed in claim 1, wherein the at least one floating heat spreader has at least one spring; an end of the at least ones spring abuts against the base plate of the at least one floating heat spreader; another end of the at least one spring abuts against an inner wall of the case; when the at least one floating heat spreader moves towards the at least one shallow groove, the base plate of the at least one floating heat spreader compresses the at least one spring.

8. The liquid-cooling heat dissipation device as claimed in claim 1, wherein a surface of the base plate of the at least one floating heat spreader facing the at least one shallow groove has a groove; the groove surrounds the plurality of fins; a side of the seal ring fits in the groove.

9. The liquid-cooling heat dissipation device as claimed in claim 1, wherein the at least one retaining structure combining portion comprises a plurality of screw holes; the plurality of screw holes are spaced and surround around the at least one shallow groove; the at least one retaining structure comprises a plurality of bolts, wherein the plurality of bolts are respectively screwed into the plurality of screw holes; each of the plurality of bolts has a head portion, wherein the head portion of each of the plurality of bolts engages with the peripheral edge of the base plate.

10. The liquid-cooling heat dissipation device as claimed in claim 9, wherein a plurality of recesses in a surrounding and spaced arrangement are formed at the peripheral edge of the base plate of the at least one floating heat spreader; the head portion of each of the plurality of bolts engages with each of the plurality of recesses.
